(19) United States
(12) Patent Application Publication
(10) Pub. No.: US 2025/0372165 A1
(43) Pub. Date: Dec. 4, 2025

(54) SYSTEM AND METHODS FOR SMART BINNING AND HEALING PROGRAMMING OF RESISTIVE RANDOM-ACCESS MEMORIES (RERAMS)

(71) Applicant: Weebit Nano Ltd., Hod Hasharon (IL)

(72) Inventor: Ilan SEVER, Kfar Vitkin (IL)

(73) Assignee: Weebit Nano Ltd., Hod Hasharon (IL)

(21) Appl. No.: 19/226,604

(22) Filed: Jun. 3, 2025

Related U.S. Application Data
(60) Provisional application No. 63/655,391, filed on Jun. 3, 2024.

(51) Int. Cl. G11C 13/00

(52) U.S. Cl. CPC G11C 13/0069; G11C 2013/0076

(57) ABSTRACT

Stress and overprogramming of resistive random-access memory (ReRAM) cells is prevented by binned programming of each ReRAM cell (bit) of a ReRAM word. Accordingly, there is performed at least one read before write (RBW) of a low resistive state (LRS) of the ReRAM for each of the plurality of the word bits and at least one read before write (RBW) of a high resistive state (HRS) of the ReRAM for each of the plurality of the word bits. Then determination as to which bin of LRS bins and a plurality of HRS each bit belongs is based on the RBW results, and weakest and strongest bins are determined. Lastly, each bit of the word is programmed based on information provided, for example, from a lookup table (LUT) and the bin association of each bit. A ReRAM device may have a control logic that has embedded therein this method.

### CROSS-REFERENCE TO RELATED APPLICATIONS

This application claims the benefit of U.S. Provisional Application No. 63/655,391 filed Jun. 3, 2024, the contents of which are hereby incorporated by reference

### TECHNICAL FIELD

The present disclosure generally relates to resistive random-access memory (ReRAM) cells, and more particularly to an improvement in setting and resetting operations of ReRAM cells.

### BACKGROUND

Resistive Random Access Memory (ReRAM) is a type of non-volatile memory that comprises a plurality of memory cells arranged in an array, where each memory cell operates based on the resistance of a material. The operation relies on the ability to have at least two different states, a low resistive state (LRS) and a high resistive state (HRS) that are clearly separable from each other. Programming a ReRAM device involves changing the resistance of the memory cell to store data. Programming of a ReRAM involves several stages: a) forming, or initialization of a ReRAM cell; b) a SET of the ReRAM cell; and c) RESET of the ReRAM cell. Thereafter, READ operations may take place to access the content of the ReRAM cell.

The forming operation is typically a one-time process used to initialize the ReRAM cell by creating a conductive path or filament that brings it to a known HRS. Prior to forming, the cell is typically in an unprogrammed state, exhibiting high resistance. The forming process creates a reliable conductive path that can be repeatedly accessed during subsequent programming and reading operations of the ReRAM cell. During forming, a forming voltage is applied across the cell.

The SET operation is used to program a ReRAM cell from an HRS to an LRS, typically representing a programmed “1” state. A set voltage is applied across the ReRAM cell, causing a localized electrochemical reaction within the resistive layer of the ReRAM cell. This reaction results in the formation of a conductive filament or bridge, reducing the resistance of the cell.

The RESET operation is the opposite operation of the SET operation and is used to program the ReRAM cell from the LRS back to the HRS, typically representing a programmed “0” state. A RESET voltage is applied across the cell in the opposite polarity, causing the conductive filament to rupture or dissolve. The result is an increase in the resistance of the cell to its high resistance state.

However, the current techniques of setting and resetting of the ReRAM cells does not take into account the actual condition of the resistances at each given state. It assumes that all ReRAM cells are born equal and therefore pass the same process. The reality is that there is a relatively large spread in both HRS values that can be from below 10KΩ to above 18KΩ, and LRS that can range from below 2KΩ to above 6KΩ. Current smart programming algorithms may use repeated pulses with the same voltage and/or duration, or an increasing voltage strategy. However, this may apply unnecessary stress to marginal ReRAM cells reducing, sometimes significantly, their endurance. That is, while nominal cells of the ReRAM would be fine with such methods, marginal cells would be likely overstressed or over-programmed thereby reducing the endurance of the ReRAM.

It would be therefore advantageous to provide a solution for setting and resetting of ReRAM cells that overcomes the deficiencies of the prior art.

### SUMMARY

A summary of several example embodiments of the disclosure follows. This summary is provided for the convenience of the reader to provide a basic understanding of such embodiments and does not wholly define the breadth of the disclosure. This summary is not an extensive overview of all contemplated embodiments, and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “some embodiments” or “certain embodiments” may be used herein to refer to a single embodiment or multiple embodiments of the disclosure.

Certain embodiments disclosed herein include a method for programming a resistive random-access memory (ReRAM), the method comprising: selecting a word of the ReRAM, the word comprising a plurality of ReRAM cells, each ReRAM cell representing a bit; performing at least one read before write (RBW) of a low resistive state (LRS) of the ReRAM for each of the plurality of the word bits; performing at least one read before write (RBW) of a high resistive state (HRS) of the ReRAM for each of the plurality of the word bits; determining to which bin of LRS bins and to which bin of HRS bins each bit of the plurality of the word bits belongs to, wherein determination is based on the LRS RBW results and the HRS RBW results, respectively, wherein a first bin of the LRS bins is a weakest LRS bin and a second bin of the LRS bins is the strongest LRS bin, and wherein a first bin of the HRS bins is a weakest HRS bin and a second bin of the HRS bins is the strongest HRS bin; and programming each bit of the selected word based on a predetermined calculation scheme and a bin in association with the each bit.

Certain embodiments disclosed herein also include a non-transitory computer readable medium having stored thereon instructions for causing a processing circuitry to execute a process for programming a resistive random-access memory (ReRAM), the process comprising: selecting a word of the ReRAM, the word comprising a plurality of ReRAM cells, each ReRAM cell representing a bit; performing at least one read before write (RBW) of a low resistive state (LRS) of the ReRAM for each of the plurality of the word bits; performing at least one read before write (RBW) of a high resistive state (HRS) of the ReRAM for each of the plurality of the word bits; determining to which bin of LRS bins and to which bin of HRS bins each bit of the plurality of word bits belongs to, wherein determination is based on the LRS RBW results and the HRS RBW results, respectively, wherein a first bin of the LRS bins is a weakest LRS bin and a second bin of the LRS bins is the strongest LRS bin, and wherein a first bin of the HRS bins is the weakest HRS bin and a second bin of the HRS bins is the strongest HRS bin; and programming each bit of the selected word based on a predetermined calculation scheme and a bin in association with the each bit.

Certain embodiments disclosed herein further include a resistive random-access memory (ReRAM) comprising: a ReRAM array, the array comprising a plurality of ReRAM cells organized in rows and columns, and furthermore, a plurality of ReRAM cells comprising a word; a bit-line decode communicatively connected to the ReRAM array; a word-line driver communicatively connected to the ReRAM array; and control logic communicatively connected to at least the bit-line decoder and the word-line driver, the control logic configured to enable reading, setting, and resetting of each ReRAM cell of the ReRAM array, and is further configured to: perform at least one read before write (RBW) of a low resistive state (LRS) of the ReRAM for each of the plurality of the word bits; perform at least one read before write (RBW) of a high resistive state (HRS) of the ReRAM for each of the plurality of the word bits; determine to which bin of LRS bins and to which bin of HRS bins each bit of the plurality of word bits belongs to, wherein the determination is based on the LRS RBW results and the HRS RBW results, respectively, wherein a first bin of the LRS bins is a weakest LRS bin and a second bin of the LRS bins is the strongest LRS bin, and wherein a first bin of the HRS bins is the weakest HRS bin and a second bin of the HRS bins is the strongest HRS bin; and program each bit of the selected word based on a predetermined calculation scheme and a bin in association with the each bit.

### BRIEF DESCRIPTION OF THE DRAWINGS

The subject matter disclosed herein is particularly pointed out and distinctly claimed in the claims at the conclusion of the specification. The foregoing and other objects, features, and advantages of the disclosed embodiments will be apparent from the following detailed description taken in conjunction with the accompanying drawings.

FIG. 1 is a graph of programming a random-access resistive memory (ReRAM) by bins according to an embodiment.

FIG. 2 is a lookup table (LUT) for high-resistance state (HRS) programming of the ReRAM according to an embodiment.

FIG. 3 is a LUT for low-resistance state (LRS) programming of the ReRAM according to an embodiment.

FIG. 4 is a method of programming the ReRAM using LRS LUT and HRS LUT according to an embodiment.

FIG. 5A is a timing diagram of performing read-before-write (RBW) of a ReRAM word according to an embodiment.

FIG. 5B is a timing diagram of performing programming of a ReRAM word according to an embodiment.

FIG. 6 is a ReRAM device configured with bin programming according to an embodiment.

### DETAILED DESCRIPTION

It is important to note that the embodiments disclosed herein are only examples of the many advantageous uses of the innovative teachings herein. In general, statements made in the specification of the present application do not necessarily limit any of the various claims. Moreover, some statements may apply to some inventive features but not to others. In general, unless otherwise indicated, singular elements may be in plural and vice versa with no loss of generality. In the drawings, like numerals refer to like parts through several views.

Stress and overprogramming of resistive random-access memory (ReRAM) cells is prevented using a method of binned programming that operates on each ReRAM word that comprises a plurality of ReRAM cells (bits). Accordingly, there is performed at least one read before write (RBW) of a low resistive state (LRS) of the ReRAM for each of the plurality of the word bits and at least one read before write (RBW) of a high resistive state (HRS) of the ReRAM for each of the plurality of the word bits. Then determination as to which bin of LRS bins and a plurality of HRS each bit belongs is based on the RBW results, and weakest and strongest bins are determined. Lastly, each bit of the word is programmed based on information provided, for example, from a lookup table (LUT), and the bin association of each bit. A ReRAM device may have a control logic that has embedded therein this method.

The disclosed invention is designed to account for the initial conditions of the bits of the ReRAM. These initial conditions are checked prior to SET or RESET operations done by using various algorithms, including smart algorithms. Accordingly, prior to these steps, a process of read operations, typically taking two cycles each on average, are performed. Overall, this is much shorter than any programming pulse. This allows the determination of the characteristics of each ReRAM cell in the range of weak to strong, and as further explained herein. For each of LRS and HRS the cells may be determined if these are nominal, marginal or far cells, data which is then used for accessing the entry in a LUT. Then when performing the SET or RESET of the ReRAM cells, the data stored in the LUT is used to ensure that the operation is as accurate as possible therefore avoiding the overstressing and/or overprogramming of each ReRAM cell. While a LUT is described herein it should be understood that other methods to calculate may be used without departing from the scope of the disclosed embodiments. As in modern ReRAM devices, digital circuitry is abundant, especially in technologies of 22 nm and below, it is straightforward and cost-effective to include the necessary circuitry to perform these functions.

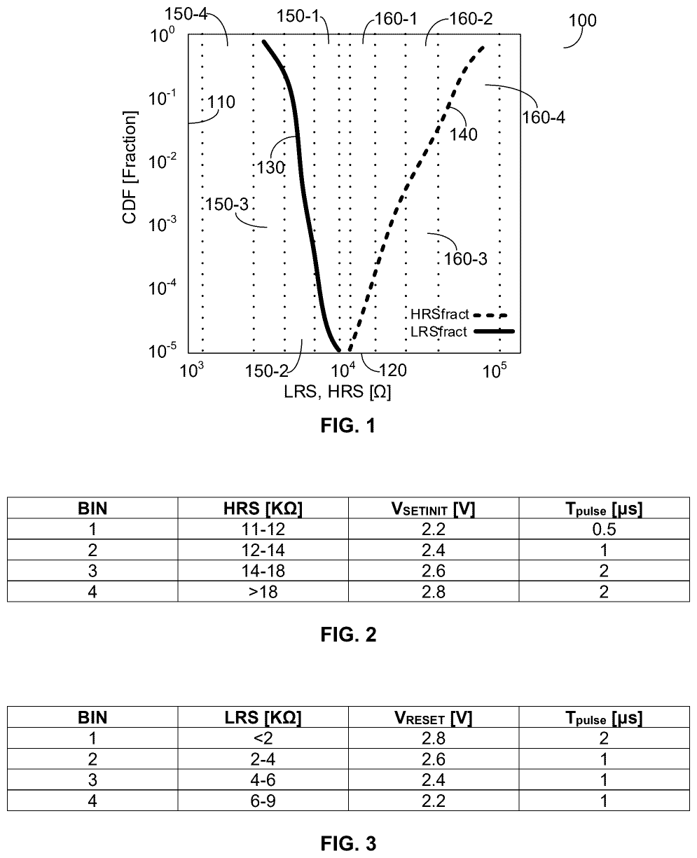

FIG. 1 shows an example graph 100 of programming a random-access resistive memory (ReRAM) by bins according to an embodiment. The horizontal axis 120 of graph 100 is the resistance of a ReRAM cell, for both LRS and HRS, in Ohms. The vertical axis 110 of graph 100 shows the cumulative distribution function (CDF) as a fraction, where CDF is a statistical tool for data representation. Basically, the CDF representation could mean that at 10⁻¹, 90% of the ReRAM cells are included. At 10⁻², 99% percent of the cells are within that range, at 10⁻³, 99.9% and so on. In other words, for the case at hand, at the range of 10⁻¹ CDF, 90% of the ReRAM cells have a resistance higher (cumulative-HRS) or lower (inverse cumulative-LRS) than the corresponding resistance value.

The LRS graph 130 and the HRS graph 140 show the respective values for each respective state. These graphs are generated, for example, by testing the resistance of each bit of a ReRAM array.

As shown at a CDF of 10⁻⁵, the example graphs come pretty close, the LRS graph 130 reaches around 8KΩ and the HRS graph 140 is at around 12KΩ. Consider now even a smaller ReRAM device having 8 Mb, approximately 80 bits will be marginal as far as the separation between LRS and HRS is concerned. As the number of bits increases in the ReRAM devices, so does the number of marginal bits.

According to an embodiment, prior SET or RESET operations, a binning process takes place to determine for each bit of the ReRAM device a particular bin to which it belongs. In this particular example, four bins are used for each of LRS and HRS, however, this should not be viewed as limiting upon the embodiments and any number of bins N may be used, where N is an integer greater than ‘1’. For the LRS, the four bins shown are 150-1, 150-2, 150-3, and 150-4. Bin 150-1 corresponds to the weakest RESET while bin 150-4 corresponds to the strongest RESET. For the HRS, the four bins shown are 160-1, 160-2, 160-3, and 160-4. Bin 160-1 corresponds to the weakest SET while bin 160-4 corresponds to the strongest SET.

It should be noted that in order to determine to which bin each bit belongs, depending on its particular initial state, several read before write (RBW) may be performed. In the case where four bins are desired for LRS, then three RBW may take place at using a resistance margin adjustment (RMA) that is set at the beginning value of each bin, and as further explained with respect to the binning tables discussed herein. Similarly, this may be performed for the LRS. Note that according to the disclosed embodiments, the minimum number of such reads is one for the case of two bins. In the general case, the number of RBW is one less than the number of bins. In an embodiment, the number of LRS bins and the number of HRS bins are the same. In another embodiment, the number of LRS bins and the number of HRS bins are different.

One of ordinary skill in the art would now appreciate the fact that the number of bits in LRS Bin 1 or HRS Bin 1, is exponentially lower than the number of bits in the respective LRS Bin 4 and HRS Bin 4. That is because while ˜90% of the bits are in LRS Bin 4 and HRS Bin 4, respectively, only ˜0.009% of the bits are in LRS Bin 1 and HRS Bin 1, respectively. According to the invention, by providing separate treatment targeted to the weaker cells, which are generally rare, accounting for approximately ˜0.1% of the bits of the ReRAM device, the overall handling time of the process of programming is not changed, but stress and overprogramming of the weaker cells of the ReRAM is avoided.

FIG. 2 is an example lookup table (LUT) for HRS programming of the ReRAM according to an embodiment. The HRS LUT contains different programming conditions for different bins depending on the bin. In the case of four bins, there are designated 3 RMAs at 10KΩ, 14KΩ, and 18KΩ, with the resultant four bins, being from HRS Bin 1 at the range <10KΩ (weak RESET), HRS Bin 2 at the range 10-14KΩ, HRS Bin 3 at the range 14-18KΩ, and HRS Bin 4 at the range >18KΩ (strong RESET). A SET voltage for Bin 1, Bin 2, Bin 3, and Bin 4, is 2.2V, 2.4V, 2.6V and 2.8V, respectively. The duration of the SET pulse is set to 0.5 μs, 1 μs, 2 μs, and 2 μs, respectively. In an embodiment the current limit (lₗᵢₘ) may also be controlled. Any of these parameters, or combinations thereof may be used in the HRS LUT in order to achieve the desired programming for each cell belonging to a bin. As a result, a ReRAM cell determined to belong to HRS Bin 1 will be programmed differently than those ReRAM cells determined to belong to other bins. Consequently, and in contrast to prior art, not all cells receive the same treatment, rather, each cell is treated based on its particular bin limitations.

FIG. 3 is an example LUT for LRS programming of the ReRAM according to an embodiment. The LRS LUT contains different programming conditions for different bins depending on the bin. In the case of four bins, there are designated 3 RMAs at 2KΩ, 4KΩ and 6KΩ, with the resultant four bins, being from LRS Bin 1 at the range <2KΩ (strong SET), LRS Bin 2 at the range 2-4KΩ, LRS Bin 3 at the range 4-6KΩ, and LRS Bin 4 at the range >6KΩ (weak SET). A RESET voltage for Bin 1, Bin 2, Bin 3, and Bin 4, is 2.8V, 2.6V, 2.4V and 2.2V. The duration of the RESET pulse is set to 2 μs, 1 μs, 1 μs, and 1 μs respectively. In an embodiment the current limit (lₗᵢₘ) may also be controlled. Any of these parameters, or combinations thereof may be used in the LRS LUT in order to achieve the desired programming for each cell belonging to a bin. As a result, a ReRAM cell determined to belong to LRS Bin 1 may be programmed differently than those ReRAM cells determined to belong to other bins. Consequently, and in contrast to prior art, not all cells receive the same treatment, rather, each cell is treated based on its particular bin limitations.

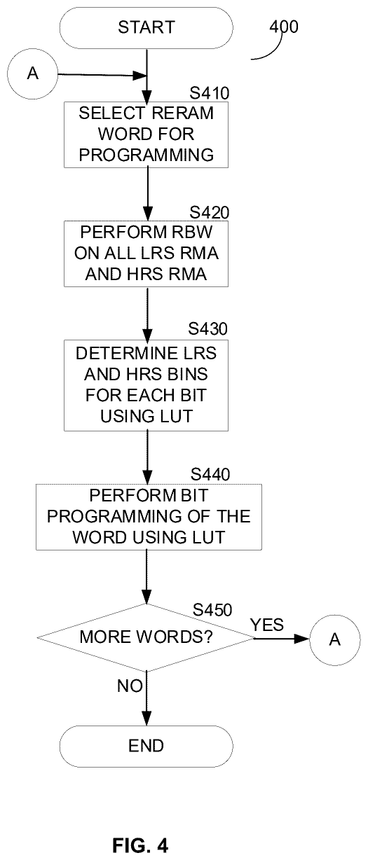

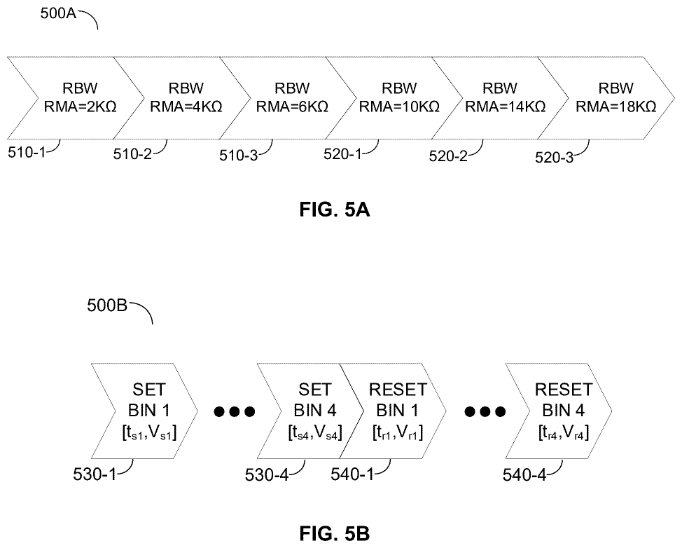

FIG. 4 is an example method 400 of programming the ReRAM using LRS LUT and HRS LUT according to an embodiment. The method uses the LUTs described in FIGS. 2 and 3, where each cell of the ReRAM is checked with respective of a predetermined RMA by performing a RBW process to determine to which one of a plurality of bins it belongs to. This determination is typically a fast and short process and is significantly shorter than any of the SET or RESET programming, and as further schematically shown in FIGS. 5A and 5B. Each bit in a word is checked to determine to which bin it should be associated with. Thereafter, the LUTs are used for determining the programming mode for each bit within a ReRAM word, thereby avoiding the stressing or overprogramming of any of the ReRAM cells. While the use of LUTs is provided herein, it should not be viewed as limiting upon the disclosed embodiments, and other predetermined methods of calculations may be used without departing from the scope of the present disclosure.

At S410, a word of a ReRAM cell to be programmed is selected. The word typically contains a plurality of bits and may be dependent on the specific architecture of the ReRAM.

At S420, each bit of the ReRAM word is checked with respect to the RMA values. For example, in the case where four bins are used for each of LRS and HRS, and as further shown in FIG. 5A, RBW is performed first on RMA of 2KΩ, then 4KΩ, and 6KΩ to cover the LRS range, and next on RMA of 10KΩ, then 14KΩ, and 18KΩ to cover the HRS range. This determines the bin to which every bit of the ReRAM word belongs to.

At S430, a programming profile is determined for each bit of the ReRAM word, to account for the determination of the bin to which the bit belongs to, as well as based on the LUT information, for example, the LUTs described in FIGS. 2 and 3. Specifically, it is determined to which bin of LRS bins and to which bin of HRS bins each bit belongs to, based on the LRS RBW results and the HRS RBW results, respectively. In an embodiment, it is performed based on the content of the LUTs.

At S440, each bit of the ReRAM is programmed according to the determination made at S430 and as further shown in FIG. 5B. It should be noted that several bits of the word all belonging to the same bin and having to be programmed to the same value, may be handled simultaneously, i.e., the process is not limited to be performed sequentially on the bits of the ReRAM word.

At S450, it is checked whether an additional ReRAM word is to be programmed and if so, execution continues with S410; otherwise, execution terminates. In an embodiment, S450 may be omitted without departing from the scope of the present disclosure.

In an embodiment, for example, instead of using the LUTs, a simple calculation may be used. The pulse width being determined as a multiplication of a constant time period, for example, 100 ns times the bin number. The V_{SET} value may be determined by adding to an initial VSET voltage, V_{SETINIT}, a value of 100 mV times the bin number. One of ordinary skill in the art would readily appreciate an advantage of the approaches described herein as they further provide for adjustment of pulse width and programming voltages per technology node (typically defined as the minimum gate width for the technology), a wafer corner (fast-fast, slow-slow, fast-slow or slow-fast), and any other desirable parameters.

It should be noted that, in an embodiment, a bitmask is used to mask bits of the word that do not need changing. That is, if a bit is at an LRS and is to remain in LRS, then the bitmask prevents the performance of programming thereon. Similarly, if a bit is at an HRS and is to remain in HRS, then the bitmask prevents the performance of programming thereon. In the case where bit healing may be necessary, then despite the bitmask. programming takes place as further explained herein.

FIG. 5A is an example timing diagram 500A of performing read-before-write (RBW) of a ReRAM word according to an embodiment. In this case, four bins are created for each of LRS and HRS of bits of a word of a ReRAM device, and as further explained in the discussion of FIG. 4 at S420. As four bins are opted for, then three read margin analysis (RMA) values are used for each of LRS and HRS, i.e., 2KΩ, 4KΩ, and 6KΩ for LRS, resulting in such bits being allocated to one of four bins, LRS Bin 1 through LRS Bin 4, and 10KΩ, 14KΩ, and 18KΩ, resulting in such bits being allocated to one of four bins, HRS Bin 1 through HRS Bin 4. Hence, in this example, 6 RBWs are performed to assign each of the bits of a ReRAM word into one of eight possible bins. The RBW is a digital process and hence is relatively fast and may take, for example, 40 ns to complete each step.

For LRS determination, RBW 510-n is performed, where ‘n’ is an integer equal to or greater than ‘1’. In this example n=3 and hence RBW 510-1, 510-2, and 510-3 are performed sequentially. For HRS determination, RBW 520-m is performed, where ‘m’ is an integer equal to or greater than ‘1’. In this example, n=3 and hence RBW 520-1, 520-2, and 520-3 are performed sequentially. The values ‘n’ and ‘m’ need not be equal. As modern ReRAM devices are manufactured using advance technologies, adding the logic to perform these functions has a reasonable cost with providing the advantage of avoiding stress or overprogramming of ReRAM bits and therefore enhancing the device's endurance.

FIG. 5B is an example timing diagram 500B of performing programming of a ReRAM word according to an embodiment. In the current example, there are four bins for each of LRS and HRS. Therefore, the performance of SET is repeated for each of LRS Bin 1 530-1 through LRS Bin 4 530-4 and as further described in the discussion of FIG. 4 at S440. Similarly, the performance of RESET is repeated for each HRS Bin 1 540-1 through LRS Bin 4 540-4. The number of LRS Bins ‘i’ is dependent on the number of LRS RMAs used ‘n’, and specifically i=n+1. Similarly, the number of HRS Bins ‘j’ is dependent on the number of LRS RMAs used ‘m’, and specifically j=m+1. In order to perform a SET or RESET certain parameters are needed, for example the parameters received from the respective LUTs shown in FIGS. 2 and 3. These may include the like of the SET pulse duration tₛ and the SET pulse amplitude Vₛ, current level limitations, or any other parameter affecting SET operation strength. Similarly, they may include the like of the RESET pulse duration tr and the RESET pulse amplitude Vᵣ, or any other parameter affecting RESET operation strength. In the described case, up to four SET operations and up to four RESET operations may take place to complete the process for an entire ReRAM word, noting that bits requiring the same programming scheme may be programmed simultaneously.

The total programming time Tₚ is therefore equal to:

$${T}_{p} = {T}_{RBW} + {\sum }_{i = 1}^{n} {t}_{{s}_{i}} + {\sum }_{j = 1}^{m} {t}_{{r}_{j}}$$

where T_{RBW}=(n+m+1)×T_{READ}, where T_{RBW} is a time to read-before-write and T_{READ} is a time to read.

As can be seen in the tables of FIGS. 2 and 3, the programming time may vary depending on the distribution of the bits in the bins, however, as noted, Bin 1 and Bin 2 of each of LRS and HRS bits are quite rare. As a result, Tₚ is typically longer in duration when compared to the prior art due to the multiple RBW occurrences due to applying separate programming pulses to separate groups of bits. However, this is an acceptable approach as this provides for improved endurance and reliability which are by far more important in ReRAM devices when weighed against programming time, i.e., the overall performance of the ReRAM device is improved.

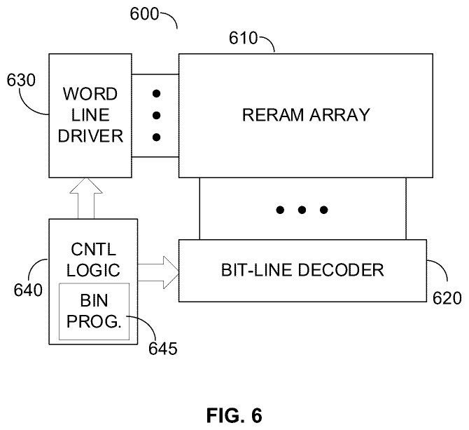

FIG. 6 is an example ReRAM device 600 configured with bin programming according to an embodiment. A ReRAM array 610 is typically organized as rows and columns of ReRAM cells, and where further ReRAM cells are organized into words of predetermined length, for example of 8, 16, or 32-bits, though it should be understood that other word lengths are possible without departing from the scope of the present disclosure. A bit-line decoder 620 communicatively connected to the ReRAM array 610, and a word-line driver 630 also communicatively connected to the ReRAM array 610 enables the access to each word of the ReRAM array 610 and either reading, forming, or programming (SET or RESET) of the bits of the word.

Control logic 640 is communicatively connected to at least the bit-line decoder 620 and the word-line driver 630 and controls the either of reading, forming, or programming (SET or RESET) of the bits of the word. This is typically performed in response to external commands and/or data received by the control logic 640. In an embodiment, the control logic 640 further comprises bin programming logic 645 that, when activated, cause the performance of the RBW of all LRS RMA and HRS RAM of bits of a word of a ReRAM (see, for example, FIG. 4 at S420 and associated description), assignment of bit programming according to LUT data (see, for example, FIG. 4 at S430 and associated description), and bit programming of the selected word (see, for example, FIG. 4 at S440 and associated description). The bin programming logic 645 may comprise of a memory containing instructions therein that are executed by the control logic 640, which may further comprise a controller. The control logic 640 may further comprise the LRS LUT and the HRS LUT of the ReRAM array 610. In one embodiment the LRS LUT and the HRS LUT are hard-wired as part of the control logic 640. In another embodiment the LRS LUT and the HRS LUT are stored in memory of the control logic 640, whether volatile or non-volatile as the case may be.

According to an embodiment, read of the RBW is performed also in bits that are not supposed to be changed. If the bit within the ReRAM word is determined to be in Bin 1 of either LRS or HRS then a weak SET or a weak RESET is applied according to the principles of programming described herein, regardless of the fact that no change of the bit is required. This provides for a healing of those bits that are weak bits. In one embodiment, one or more weak bins, for example Bin 1 and Bin 2 may be identified as being relatively weak and therefore, regardless of if the bit is to change or not, the bit is programmed according to the principles described herein. This provides for healing of the content of the bit and ensures long-term retention of the data and improves the reliability of the memory content.

Certain embodiments disclosed herein can be implemented as hardware, firmware, software, or any combination thereof. Moreover, the software is preferably implemented as an application program tangibly embodied on a program storage unit or computer readable medium consisting of parts, or of certain devices and/or a combination of devices. The application program may be uploaded to, and executed by, a machine comprising any suitable architecture. Preferably, the machine is implemented on a computer platform having hardware processing circuits such as one or more central processing units (“CPUs”), a memory, and input/output interfaces. The computer platform may also include an operating system and microinstruction code. The various processes and functions described herein may be either part of the microinstruction code or part of the application program, or any combination thereof, which may be executed by a CPU, whether or not such a computer or processor is explicitly shown. In addition, various other peripheral units may be connected to the computer platform such as an additional data storage unit and a printing unit. Furthermore, a non-transitory computer-readable medium is any computer-readable medium except for a transitory propagating signal.

All examples and conditional language recited herein are intended for pedagogical purposes to aid the reader in understanding the principles of the disclosed embodiment and the concepts contributed by the inventor to furthering the art and are to be construed as being without limitation to such specifically recited examples and conditions. Moreover, all statements herein reciting principles, aspects, and embodiments of the disclosed embodiments, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

It should be understood that any reference to an element herein using a designation such as “first,” “second,” and so forth does not generally limit the quantity or order of those elements. Rather, these designations are generally used herein as a convenient method of distinguishing between two or more elements or instances of an element. Thus, a reference to first and second elements does not mean that only two elements may be employed there or that the first element must precede the second element in some manner. Also, unless stated otherwise, a set of elements comprises one or more elements.

As used herein, the phrase “at least one of” followed by a listing of items means that any of the listed items can be utilized individually, or any combination of two or more of the listed items can be utilized. For example, if a system is described as including “at least one of A, B, and C,” the system can include A alone; B alone; C alone; 2A; 2B; 2C; 3A; A and B in combination; B and C in combination; A and C in combination; A, B, and C in combination; 2A and C in combination; A, 3B, and 2C in combination; and the like.

What is claimed is:

1. A method for programming a resistive random-access memory (ReRAM), the method comprising:
selecting a word of the ReRAM, the word comprising a plurality of ReRAM cells, each ReRAM cell representing a bit;
performing at least one read before write (RBW) of a low resistive state (LRS) of the ReRAM for each of the plurality of the word bits;
performing at least one read before write (RBW) of a high resistive state (HRS) of the ReRAM for each of the plurality of the word bits;
determining to which bin of LRS bins and to which bin of HRS bins each bit of the plurality of the word bits belongs to, wherein determination is based on the LRS RBW results and the HRS RBW results, respectively, wherein a first bin of the LRS bins is a weakest LRS bin and a second bin of the LRS bins is the strongest LRS bin, and wherein a first bin of the HRS bins is a weakest HRS bin and a second bin of the HRS bins is the strongest HRS bin; and
programming each bit of the selected word based on a predetermined calculation scheme and a bin in association with the each bit.

2. The method of claim 1, wherein the predetermined calculation scheme further comprises:
providing information for the calculation scheme from a lookup table (LUT).

3. The method of claim 2, wherein the LUT comprises an LRS LUT and an HRS LUT.

4. The method of claim 2, wherein the LUT comprises a plurality of rows, each row comprises programming information for a predetermined bin of a plurality of bins.

5. The method of claim 4, wherein the programming information includes a length of a pulse period for applying a predetermined voltage for a bin of the plurality of bins.

6. The method of claim 4, wherein the programming information includes a predetermined voltage for the predetermined bin.

7. The method of claim 4, wherein the programming information includes a predetermined current limitation for the predetermined bin.

8. The method of claim 1, further comprising:
employing a bitmask to prevent programming of bits of the word that do not change at a particular programming cycle.

9. The method of claim 8, further comprising:
programming a masked bit of the word upon determination that the masked bit belongs to a weak bin.

10. The method of claim 1, wherein the predetermined calculation scheme is adaptable for at least one of: technology node and wafer corner.

11. A non-transitory computer readable medium having stored thereon instructions for causing a processing circuitry to execute a process for programming a resistive random-access memory (ReRAM), the process comprising:
selecting a word of the ReRAM, the word comprising a plurality of ReRAM cells, each ReRAM cell representing a bit;
performing at least one read before write (RBW) of a low resistive state (LRS) of the ReRAM for each of the plurality of the word bits;
performing at least one read before write (RBW) of a high resistive state (HRS) of the ReRAM for each of the plurality of the word bits;
determining to which bin of LRS bins and to which bin of HRS bins each bit of the plurality of word bits belongs to, wherein determination is based on the LRS RBW results and the HRS RBW results, respectively, wherein a first bin of the LRS bins is a weakest LRS bin and a second bin of the LRS bins is the strongest LRS bin, and wherein a first bin of the HRS bins is a weakest HRS bin and a second bin of the HRS bins is the strongest HRS bin; and
programming each bit of the selected word based on a predetermined calculation scheme and the bin association of the each bit.

12. A resistive random-access memory (ReRAM) comprising:
a ReRAM array, the array comprising a plurality of ReRAM cells organized in rows and columns, wherein the plurality of ReRAM cells comprises a word;
a bit-line decoder communicatively connected to the ReRAM array;
a word-line driver communicatively connected to the ReRAM array; and
a control logic communicatively connected to at least the bit-line decoder and the word-line driver, wherein the control logic is configured to enable reading, setting, and resetting of each ReRAM cell of the ReRAM array, and is further configured to:
perform at least one read before write (RBW) of a low resistive state (LRS) of the ReRAM for each of the plurality of the word bits;
perform at least one read before write (RBW) of a high resistive state (HRS) of the ReRAM for each of the plurality of the word bits;
determine to which bin of LRS bins and to which bin of HRS bins each bit of the plurality of word bits belongs to, wherein the determination is based on the LRS RBW results and the HRS RBW results, respectively, wherein a first bin of the LRS bins is a weakest LRS bin and a second bin of the LRS bins is the strongest LRS bin, and wherein a first bin of the HRS bins is the weakest HRS bin and a second bin of the HRS bins is the strongest HRS bin; and
program each bit of the selected word based on a predetermined calculation scheme and a bin in association with the each bit.

13. The ReRAM of claim 12, wherein the predetermined calculation scheme comprises information provided from a lookup table (LUT).

14. The ReRAM of claim 13, wherein the LUT comprises an LRS LUT and an HRS LUT.

15. The ReRAM of claim 13, wherein the LUT comprises a plurality of rows, each row comprises programming information for a predetermined bin of a plurality of bins.

16. The ReRAM of claim 15, wherein the programming information includes a length of a pulse period for applying a predetermined voltage for a bin of the plurality of bins.

17. The ReRAM of claim 15, wherein the programming information includes a predetermined voltage for the predetermined bin.

18. The ReRAM of claim 15, wherein the programming information includes a predetermined current limitation for the predetermined bin.

19. The ReRAM of claim 12, wherein the control logic is further configured to:
employ a mask to prevent programming bits of the word that do not change at a particular programming cycle.

20. The ReRAM of claim 19, wherein the control logic is further configured to:
program a masked bit of the word if the masked bit belongs to a weak bin.

21. The ReRAM of claim 12, wherein the predetermined calculation scheme is adaptable for at least one of: technology node and wafer corner.
